(19) United States
(12) Patent Application Publication
(10) Pub. No.: US 2016/0307811 A1
(43) Pub. Date: Oct. 20, 2016

(54) METHOD OF FORMING A TEST STRUCTURE FOR DETECTING BAD PATTERNS, AND METHOD OF DETECTING BAD PATTERNS USING THE SAME

(71) Applicant: SAMSUNG ELECTRONICS CO., LTD., SUWON-SI (KR)

(72) Inventors: JONG-HYUN LEE, SUWON-SI (KR); CHIN KIM, SEONGNAM-SI (KR)

(21) Appl. No.: 15/000,644

(22) Filed: Jan. 19, 2016

(30) Foreign Application Priority Data
Apr. 16, 2015 (KR) 10-2015-0054060

(51) Int. Cl. H01L 21/66; G01R 3/00; G01R 31/04

(52) U.S. Cl. CPC H01L 22/14; G01R 31/041; G01R 3/00

(57) ABSTRACT

A method of forming a test structure for detecting bad patterns includes classifying patterns in a chip into a plurality of groups, designing a layout of chains, the chains being formed by connecting the patterns in each of the groups to each other, and forming a test structure having the layout of chains in a region of the chip.

### CROSS-REFERENCE TO RELATED APPLICATION

The present application claims, under 35 USC §119, priority to and the benefit of Korean Patent Application No. 10-2015-0054060, filed on Apr. 16, 2015, in the Korean Intellectual Property Office (KIPO), the entire contents of which are incorporated by reference herein.

### BACKGROUND

1. Technical Field

Exemplary embodiments relate to a method of forming a test structure for detecting bad patterns, and a method of detecting bad patterns using the same. More particularly, exemplary embodiments relate to a method of forming a test structure for detecting bad patterns including vias or contacts and wirings, and a method of detecting bad patterns using the same.

2. Description of the Related Art

In order to test bad patterns of vias or contacts in a chip, a current may be applied to the vias and wirings electrically connected thereto so as to measure a resistance thereof. However, the vias and the wirings may be formed of various types in the chip, and thus detecting bad patterns in the vias and the wirings is not easy.

### SUMMARY

Exemplary embodiments provide a method of forming a test structure for detecting bad patterns. Exemplary embodiments provide a method of detecting bad patterns using the test structure.

According to exemplary embodiments, there is provided a method of forming a test structure for detecting bad patterns. The method includes classifying patterns in a chip into a plurality of groups, designing a layout of chains, the chains being formed by connecting the patterns in each of the groups to each other, and forming a test structure having the layout of chains in a region of the chip.

In exemplary embodiments, when the patterns in the chip are classified into the plurality of groups, a plurality of target regions, each of which may include target patterns, may be defined in the chip. At least one of the target patterns substantially the same as or similar to each other may be selected by comparing the target patterns in the target regions to each other to classify the at least one of the target patterns into a corresponding one of the groups.

In exemplary embodiments, when the patterns in the chip are classified into the plurality of groups, all of the target patterns in the chip may be searched to classify the searched target patterns into the plurality of groups.

In exemplary embodiments, after the plurality of target regions are defined in the chip, a portion of each of the target patterns close to an edge of each of the target regions having a size smaller than those of other portions of each of the target patterns may be removed.

In exemplary embodiments, the target patterns may include a via, and upper and lower wirings connected to top and bottom surfaces of the via.

In exemplary embodiments, when the patterns in the chip are classified into the plurality of groups, shapes of the upper and lower wirings or a location of the via between the upper and lower wirings may be considered.

In exemplary embodiments, when the patterns in the chip are classified into the plurality of groups, widths and directions of the upper and lower wirings may be considered.

In exemplary embodiments, when the layout of the chains are designed, an upper connection pattern connecting the upper wirings of neighboring ones of the target patterns, or forming a lower connection pattern connecting the lower wirings of neighboring ones of the target patterns may be formed to form the chains.

In exemplary embodiments, the upper connection pattern may be formed between an odd-numbered one and an even-numbered one of the target patterns in each of the groups, and the lower connection pattern may be formed between the even-numbered one and the odd-numbered one of the target patterns in each of the groups.

In exemplary embodiments, the upper connection pattern or the lower connection pattern may extend in a first direction, or may include a first portion extending in the first direction and a second direction extending in a second direction substantially perpendicular to the first direction.

In exemplary embodiments, the upper wiring or the lower wiring may contact the via and may extend in the first direction, and the upper connection pattern or the lower connection pattern corresponding thereto may be connected to end portions of the upper wiring or the lower wiring relatively distant from the via among end portions of the upper wiring or the lower wiring in the first direction.

In exemplary embodiments, the upper wiring or the lower wiring may include a first portion contacting the via and extending in the first direction and a second portion extending in a second direction substantially perpendicular to the first direction, and the upper connection pattern or the lower connection pattern corresponding thereto may be connected to end portions of the upper wiring or the lower wiring relatively distant from the via among end portions of the upper wiring or the lower wiring in the first and second directions.

In exemplary embodiments, after the patterns in the chip are classified into the plurality of groups, at least one of the groups having a low possibility of failure may be removed.

In exemplary embodiments, designing the layout of the chains formed by connecting patterns in each of the groups to each other may be automatically performed by programming.

According to exemplary embodiments, there is provided a method of forming a test structure for detecting bad patterns. In the method, i) a plurality of target regions each of which includes target patterns is defined in a chip. ii) the target patterns in the target regions are compared to each other to classify the compared target patterns into a plurality of groups. iii) the target patterns in each of the groups are connected to form chains.

In exemplary embodiments, each of the target patterns may include a via, and upper and lower wirings connected to top and bottom surfaces of the via.

In exemplary embodiments, steps i), ii) and iii) may be automatically performed by programming to design a layout of the chains, and the method may further include forming a test structure by forming a layout of the chains in a region of the chip.

According to exemplary embodiments, there is provided a method of detecting bad patterns. In the method, patterns in a chip are classified into a plurality of groups. A layout of chains formed by connecting patterns in each of the groups to each other is designed. Chains having the designed layout are formed in a region of the chip as a test structure. The bad patterns in the patterns are detected by applying a current to the test structure to measure a resistance thereof.

In exemplary embodiments, when patterns in the chip are classified into the plurality of groups, a plurality of target regions each of which may include target patterns may be defined in the chip. At least one of the target patterns substantially the same as or similar to each other may be selected by comparing the target patterns in the target regions to each other to classify the at least one of the target patterns into a corresponding one of the groups.

In exemplary embodiments, the target patterns may include a via, and upper and lower wirings connected to top and bottom surfaces of the via.

In exemplary embodiments, when the patterns in the chip are classified into the plurality of groups, shapes of the upper and lower wirings or a location of the via between the upper and lower wirings may be considered.

In the method of detecting bad patterns in accordance with exemplary embodiments, all target patterns existing in the chip may be searched and classified into a plurality of groups, and various types of chains may be formed according to characteristics of elements of the target patterns. All these steps may be automatically performed by programming, so that the layout of the chains may be designed. According to the designed layout of chains, the chains may be formed in the chip as a test structure, and a resistance between end portions of the test structure may be measured to exactly and easily detect bad patterns or failures in the patterns of the chip.

### BRIEF DESCRIPTION OF THE DRAWINGS

FIG. 1 is a flowchart illustrating stages of a method of forming a test structure for detecting bad patterns in accordance with exemplary embodiments.

FIGS. 2, 3, 4, 5A, 5B, 6A, 6B, 6C, 6D, 7A, 7B and 7C are plan views of target regions, target patterns and chains in order to illustrate the method of forming the test structure.

FIG. 8 is a flowchart illustrating stages of a method of detecting bad patterns in accordance with exemplary embodiments.

FIG. 9 is a flowchart illustrating stages of a method of manufacturing a semiconductor device in accordance with exemplary embodiments.

FIG. 10 is a plan view of a wafer on which the semiconductor device may be formed.

FIGS. 11, 12, 13, 14, 15, 16, 17, 18, 19, 20, 21, 22, 23, 24A, 24B, 25, 26, 27, 28, 29, 30, 31, 32, 33, 34, 35, 36, 37 and 38 are plan views and cross-sectional views illustrating the method of manufacturing the semiconductor device.

### DESCRIPTION OF EMBODIMENTS

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Also, the term “exemplary” is intended to refer to an example or illustration.

It will be understood that, although the terms first, second, third, fourth and the like may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

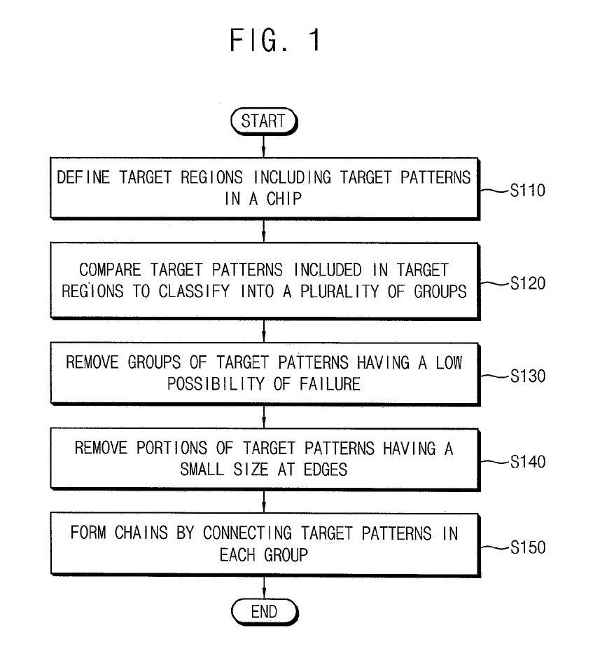

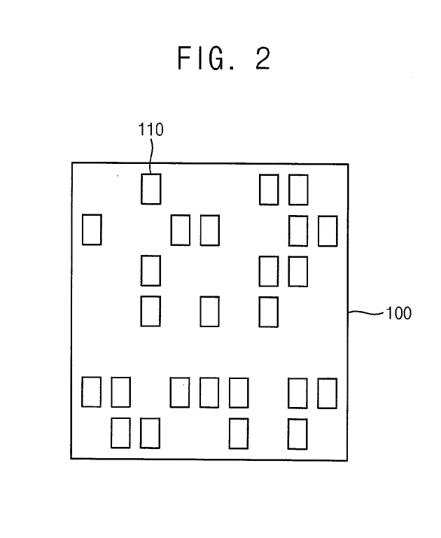

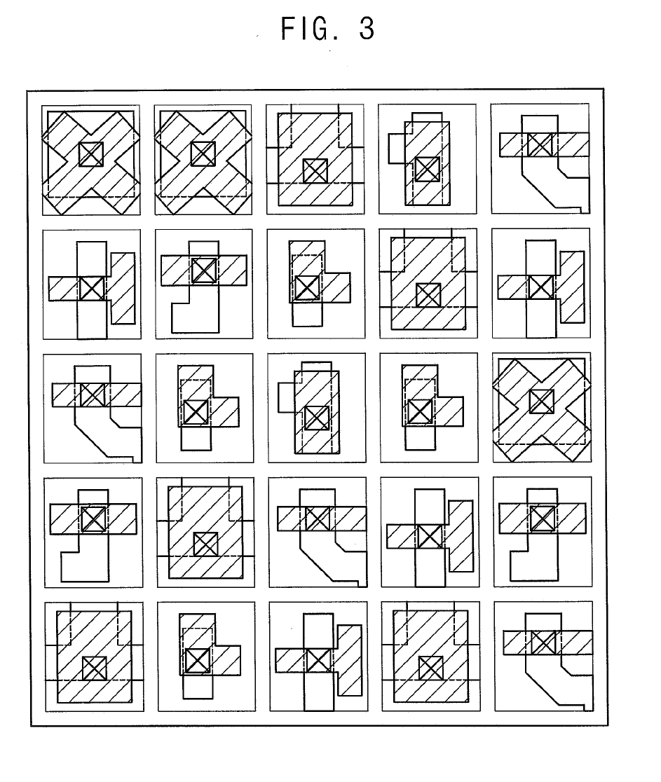

FIG. 1 is a flowchart illustrating stages of a method of forming a test structure for detecting bad patterns in accordance with exemplary embodiments, and FIGS. 2 to 7A, 7B, 7C are plan views of target regions, target patterns and chains in order to illustrate the method of forming the test structure.

Referring to FIGS. 1 and 2, in step S110, a plurality of target regions 110, each of which may include target patterns, may be defined in a chip 100.

In exemplary embodiments, each target pattern may include a via, and upper and lower wirings that may be formed on and beneath the via, respectively. Alternatively, each target pattern may include a contact, and a via and a wiring on the contact. However, the inventive concepts may not be limited thereto, and any pattern including a plurality of conductive structures contacting each other to be electrically connected to each other may be the target pattern.

The plurality of target regions 110 having the target patterns, which may be tested for detecting bad patterns among elements in the chip 100, e.g., vias, and upper and lower wirings, may be defined in the chip 100, and each of the target regions 110 may be defined in any portion of the chip 100. In exemplary embodiments, the target regions 110 may have substantially the same shape and size. FIG. 2 shows that each of the target regions 110 has a rectangular shape in a plan view. However, the shapes of the target regions 110 may not be limited thereto. In some cases, the target regions 110 may have sizes different from each other.

Referring to FIGS. 1 to 3, in step S120, the target patterns included in each of the target regions 110 may be searched to be enumerated so that the target patterns may be compared to each other. In exemplary embodiments, all target patterns in the target regions 110 defined in the chip 100 may be searched to be enumerated.

Referring to FIGS. 1 to 4, in step S120, all of the target patterns, which have been searched to be enumerated, may be compared to each other to be classified into a plurality of groups.

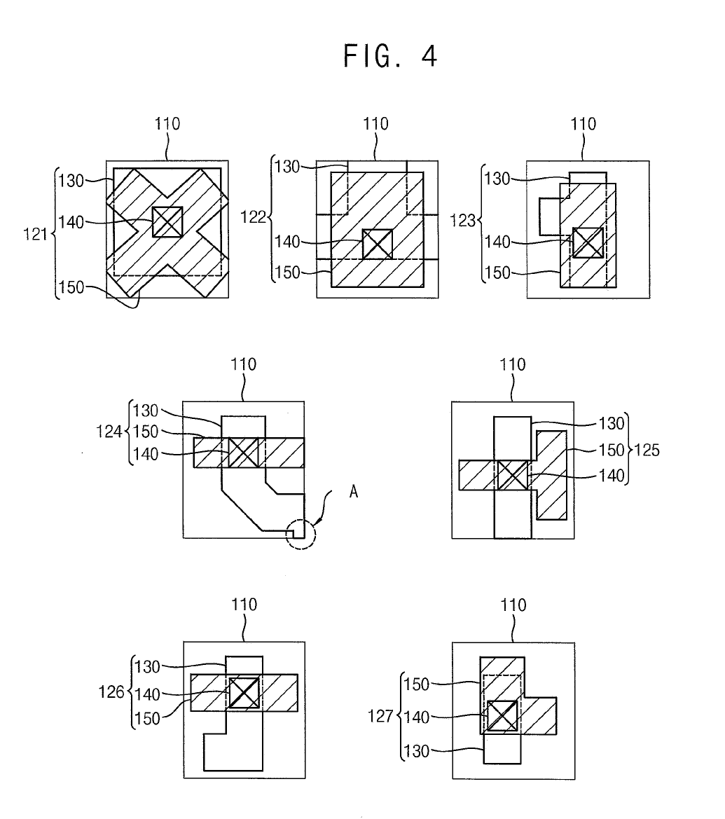

FIG. 4 shows that the target patterns are classified into first to seventh target patterns 121, 122, 123, 124, 125, 126, 127. However, the inventive concepts may not be limited thereto, and the target patterns may be classified into more or less than seven groups. Each of the first to seventh target patterns 121, 122, 123, 124, 125, 126, 127 may include a lower wiring 130, a via 140 and an upper wiring 150 sequentially stacked, which may contact each other to be electrically connected to each other.

In exemplary embodiments, the target patterns may be classified into the first to seventh target patterns 121, 122, 123, 124, 125, 126, 127 in consideration of the relative locations of the lower and upper wirings 130, 150 with respect to the via 140, contact areas between the lower and upper wirings 130, 150 and the via 140, widths and/or thicknesses of the lower and upper wirings 130, 150, and the like.

In exemplary embodiments, only one or some of the plurality of target patterns, which may be substantially the same as or similar to each other, may be classified into a corresponding group of target patterns.

Referring to FIG. 1 again, in step S130, one or some groups of target patterns among the plurality of groups, which may be determined to have a very low possibility of failure, may be removed.

For example, in the first target pattern 121 shown in FIG. 4, the via 140 may contact an upper central surface of the lower wiring 130 and a lower central surface of the upper wiring 150 at sufficient areas, respectively, and thus the possibility of contact failure therebetween may be very low. Accordingly, measuring a resistance by applying a current to end portions of a chain including the first target pattern 121 so as to detect the failure in the first target pattern 121 may be meaningless. Thus, the first target pattern 121 may be removed from the groups of target patterns each of which may form a chain and bad patterns in the chain may be detected.

Referring to FIGS. 1, 4 and 5A, in step S140, a portion of the target pattern having a relatively small size at an edge of the target region 110 may be removed to form a revised target pattern.

When a portion of a target pattern close to an edge of each of the target regions 110 is smaller than other portions of the target pattern of each of the target regions 110, the portion may be removed to form the revised target pattern.

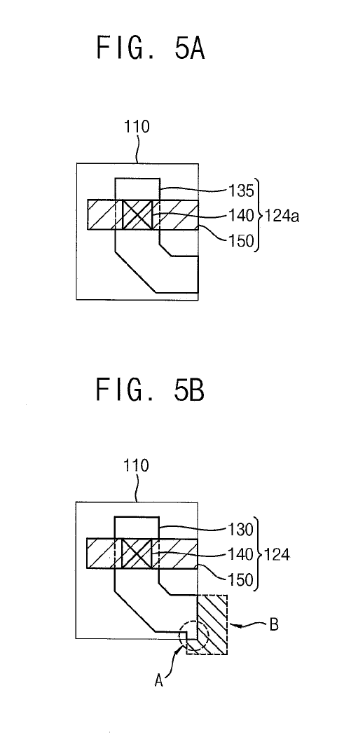

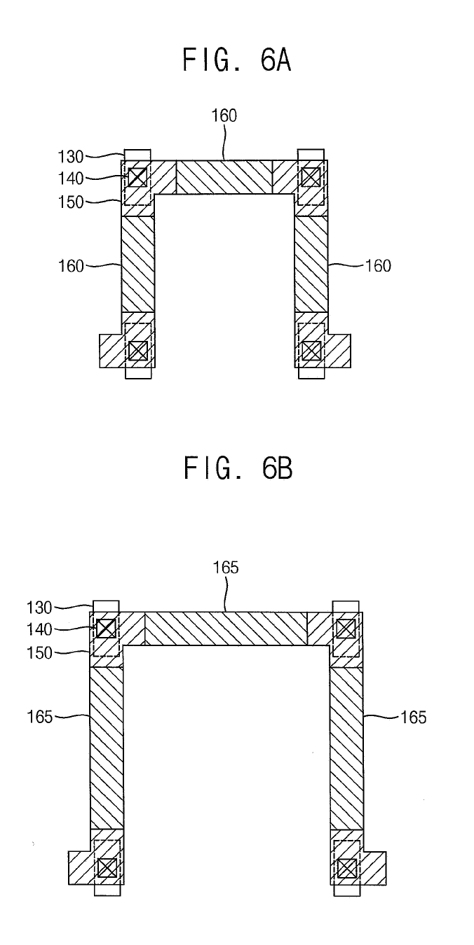

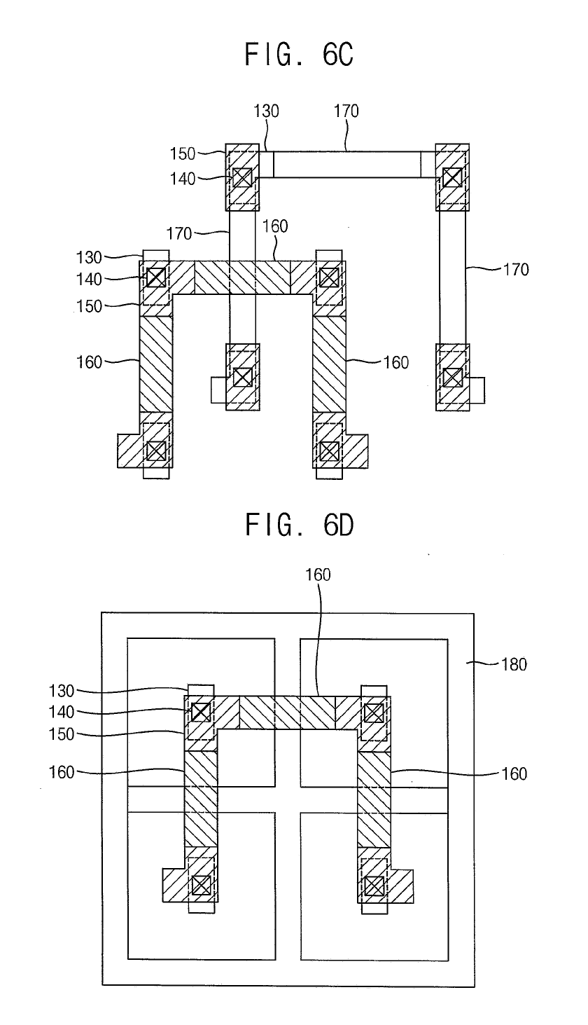

FIGS. 5A and 6B show that a portion A of the fourth target pattern 124 is removed to form a revised target pattern 124a. Referring to FIG. 5B, when a portion B at an outside of the target region 110 is also considered, the lower wiring 130 of the fourth target pattern 124 may have a constant width or thickness, however, when only an inside of the target region 110 is considered, the portion A close to an edge of the target region 110 may have a size smaller than those of other portions of the fourth target pattern 124. Thus, if a chain is formed using the fourth target pattern 124 including the portion A, measuring a resistance between end portions of the chain may not be exactly performed, and thus detecting bad patterns may be difficult. Accordingly, the portion A of the fourth target pattern 124 may be removed to form the revised fourth target pattern 124a, so that bad patterns may be easily detected.

Referring to FIGS. 6A, 6B, 6C and 6D, in step S150, the target patterns that have been classified into the plurality of groups may be connected to each other to form chains.

The groups of target patterns removed in step S130 due to the very low possibility of failure may not be used for forming the chains, and, further, the revised target patterns in step S140 may be used for forming the chains. FIGS. 6A to 6D illustrate some types of chains that may be formed using connection patterns, and for the convenience of explanation, instead of the first to seventh target patterns 121, 122, 123, 124, 125, 126, 127, simpler patterns including the lower wiring 130, the via 140 and the upper wiring 150 are shown in FIGS. 6A to 6D.

In exemplary embodiments, connection patterns 160, 170, which may connect some portions of the target patterns to each other, may be formed to form the chains. The upper connection pattern 160 may connect the upper wirings 150 to each other, and the lower connection pattern 170 may connect the lower wirings 130 to each other.

The chains may be formed in various types. For example, a single chain may be formed as shown in FIG. 6A, an intertwined chain may be formed as shown in FIG. 6C, and a conductive structure 180 may be further formed adjacent the chain as shown in FIG. 6D. Referring to FIG. 6B, a chain may be formed to include a connection pattern 165 having a length greater than that of the connection pattern 160 in FIG. 6A.

The chain in FIG. 6B may be formed in consideration of a pitch of the target patterns or the order of formation of the target patterns. The chain in FIG. 6C may be formed in consideration of the interaction between neighboring target patterns. The chain in FIG. 6D may be formed in consideration of the effect of other conductive structures adjacent the target patterns.

The types of the chains shown in FIGS. 6A to 6D are illustrative of a few representative embodiments, and other types of chains may be also formed.

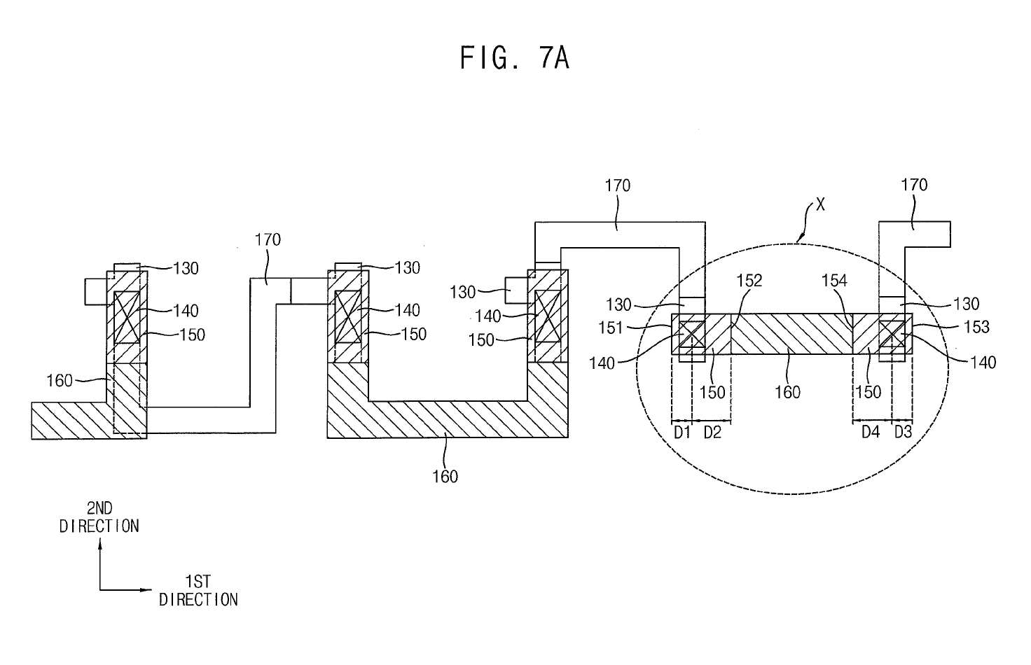

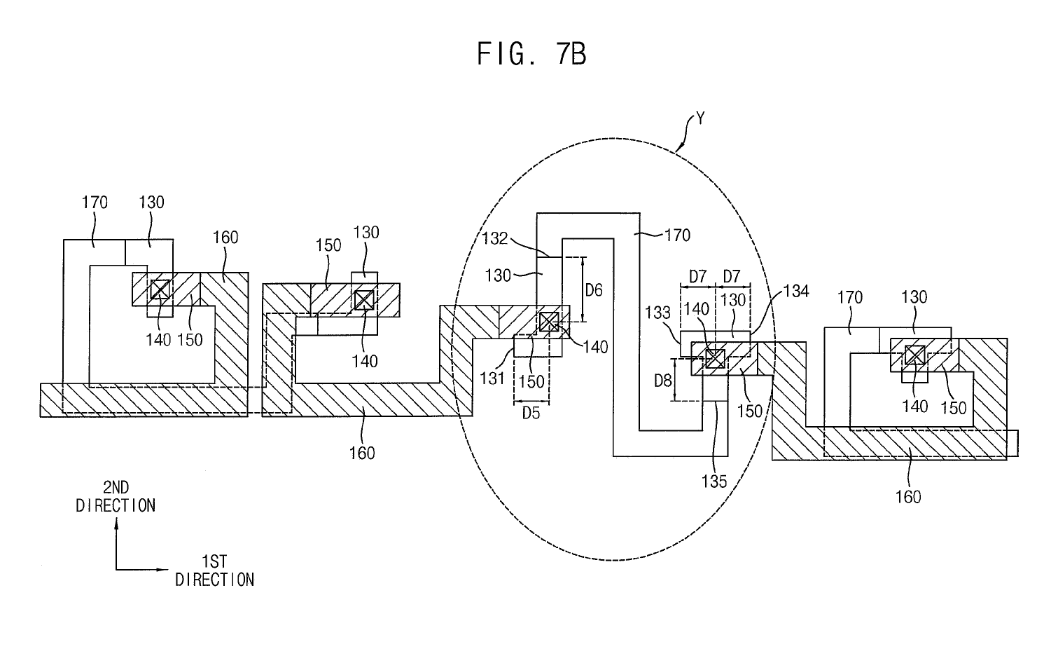

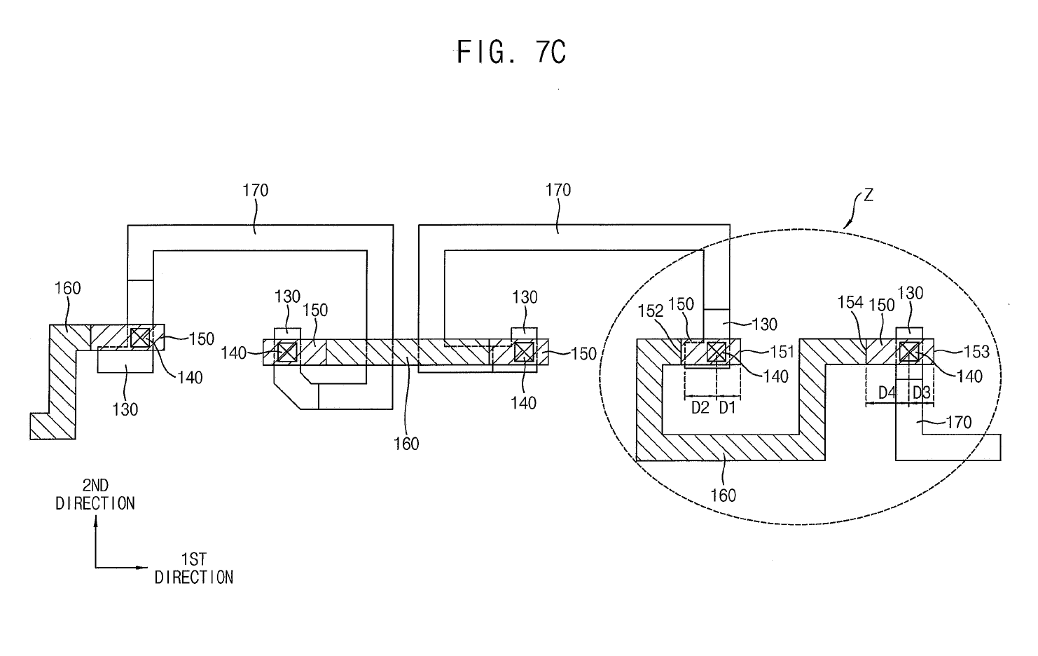

FIGS. 7A, 7B and 7C are plan views of chains formed by connecting some of the target patterns in accordance with exemplary embodiments.

Referring to FIGS. 7A to 7C, a plurality of target patterns each of which may include the via 140, the lower wiring 130 contacting a bottom surface of the via 140, and the upper wiring 150 contacting a top surface of the via 140, may be electrically connected to each other through the connection patterns 160, 170 to form chains. Particularly, the lower wirings 130 of the target patterns may be electrically connected to each other through the lower connection pattern 170 to form the chains, and the upper wirings 150 of the target patterns may be electrically connected to each other through the upper connection pattern 160 to form the chains.

The connection patterns 160, 170 may be formed taking into consideration the widths of neighboring ones of the upper wirings 150 or neighboring ones of the lower wirings 130. For example, target patterns including the upper wirings 150 having substantially the same width in the groups of target patterns may be selected, and the upper connection pattern 160 having substantially the same width as that of the upper wirings 150 of the selected target patterns may be formed therebetween to form the chains. Similarly, target patterns including the lower wirings 130 having substantially the same width in the groups of target patterns may be selected, and the lower connection pattern 170 having substantially the same width as that of the lower wirings 130 of the selected target patterns may be formed therebetween to form the chains.

In exemplary embodiments, among the plurality of target patterns forming a chain, the upper connection pattern 160 may be formed between an odd-numbered target pattern and an even-numbered target pattern along a direction, and the lower connection pattern 170 may be formed between the even-numbered target pattern and the odd-numbered target pattern along the direction. That is, the upper and lower connection patterns 160, 170 may be alternately formed between the plurality of target patterns in the direction to form the chains.

The upper connection pattern 160 or the lower connection pattern 170 may extend in a first direction, or may include a first portion extending in the first direction and a second portion extending in a second direction substantially perpendicular to the first direction.

In exemplary embodiments, the connection patterns 160, 170 may be formed in consideration of the directions of the upper wirings 150 or the lower wirings 130 of neighboring ones of the target patterns.

For example, referring to a region X of FIG. 7A, each of the upper wirings 150 may contact the via 140 and extend in the first direction, and a corresponding one of the upper connection patterns 160 may extend in the first direction to be connected to end portions 152, 154 of the upper wirings 150, which may be relatively distant from the via 140 among end portions 151, 152, 153, 154 of the upper wirings 150 in the first direction. That is, second and fourth distances D2, D4 from the second and fourth end portions 152, 154 of the upper wirings 150 to center points of the vias 140, respectively, may be greater than first and third distances D1, D3 from the first and third end portions 151, 153 of the upper wirings 150 to the center points of the vias 140, respectively, and thus the upper connection pattern 160 may be formed to connect the second and fourth end portions 152, 154 of the upper wirings 150 to each other.

Referring to a region Y of FIG. 7B, each of the lower wirings 130 may include a first portion contacting the via 140 and extending in the first direction, and a second portion extending in a second direction substantially perpendicular to the first direction. A corresponding one of the lower connection patterns 170 may extend in the first and second directions to be connected to end portions 132, 135 of the lower wirings 130, which may be relatively distant from the via 140 among end portions 131, 132, 133, 134, 135 of the lower wirings 130 in the first and second directions. That is, sixth and eighth distances D6, D8 from the second and fifth end portions 132, 135 of the lower wirings 130 to center points of the vias 140, respectively, may be greater than fifth and seventh distances D5, D7 from the first, third and fourth end portions 131, 133, 134 of the lower wirings 130 to the center points of the vias 140, respectively, and thus the lower connection pattern 170 may be formed to connect the second and fifth end portions 132, 135 of the lower wirings 130 to each other.

Referring to a region Z of FIG. 7C, each of the upper wirings 150 may contact the via 140 and extend in the first direction, and a corresponding one of the upper connection patterns 160 may extend in the first and second directions to be connected to the end portions 152, 154 of the upper wirings 150, which may be relatively distant from the via 140 among the end portions 151, 152, 153, 154 of the upper wirings 150 in the first direction. That is, the second and fourth distances D2, D4 from the second and fourth end portions 152, 154 of the upper wirings 150 to the center points of the vias 140, respectively, may be greater than the first and third distances D1, D3 from the first and third end portions 151, 153 of the upper wirings 150 to the center points of the vias 140, respectively, and thus the upper connection pattern 160 may be formed to connect the second and fourth end portions 152, 154 of the upper wirings 150 to each other.

FIGS. 7A to 7C show non-limiting examples of a method of forming chains taking into consideration the width or direction of the target patterns, and the inventive concepts may not be limited thereto. Close patterns according to the reduction of design rule may not be simultaneously formed but may be formed in separate processes, and the chains may be formed in consideration of the separate processes also.

As illustrated above, all target patterns existing in the chip 100 may be searched and classified into a plurality of groups through steps S110, S120, S130, S140, S150, and various types of chains may be formed according to characteristics of elements of the target patterns, and all these steps may be automatically performed by programming, so that the layout of the chains may be designed.

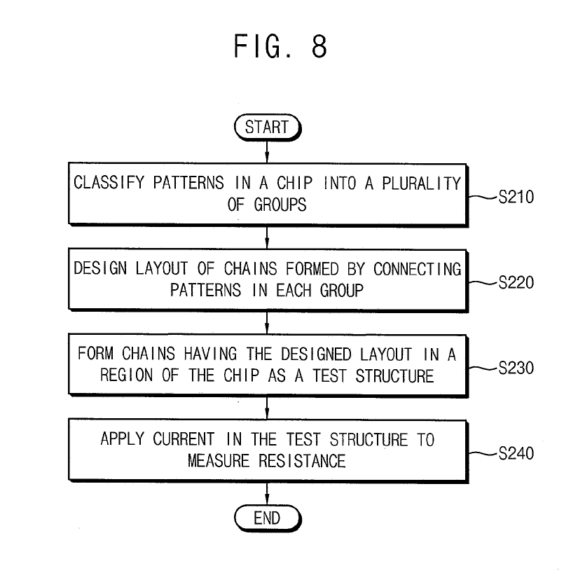

FIG. 8 is a flowchart illustrating stages of a method of detecting bad patterns in accordance with exemplary embodiments. This method may be performed using the method of forming the test structure for detecting bad patterns illustrated with reference to FIGS. 1 to 7A, 7B, 7C.

Referring to FIG. 8, in steps S210 and S220, steps S110, S120, S130, S140 and S150 illustrated with reference to FIGS. 1 to 7A, 7B, 7C may be performed, and thus the patterns in the chip may be classified into a plurality of groups, and the patterns in each of the plurality of groups may be connected to form chains, which may be automatically performed by programming to design the layout of the chains.

In step S230, the chains having the designed layout may be formed in a region of an inside of the chip as a test structure.

In step S240, a current may be applied to the test structure to measure a resistance, so that bad patterns or failure in the patterns may be detected.

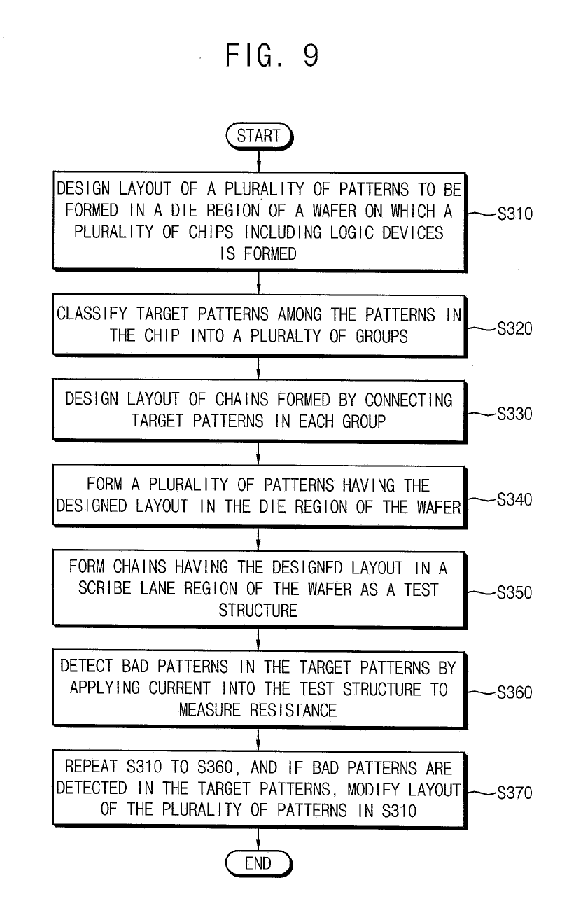

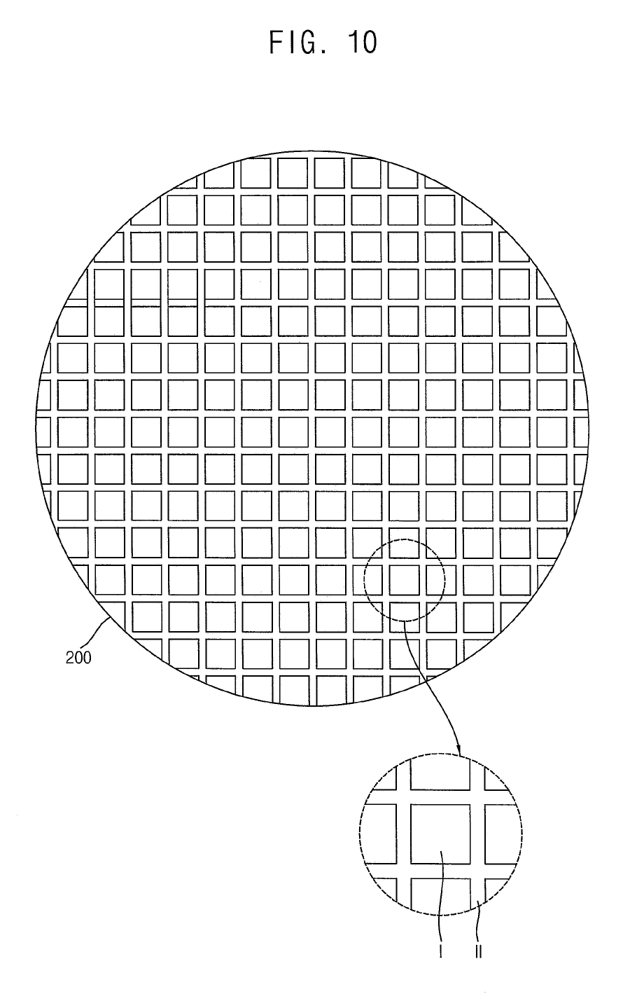

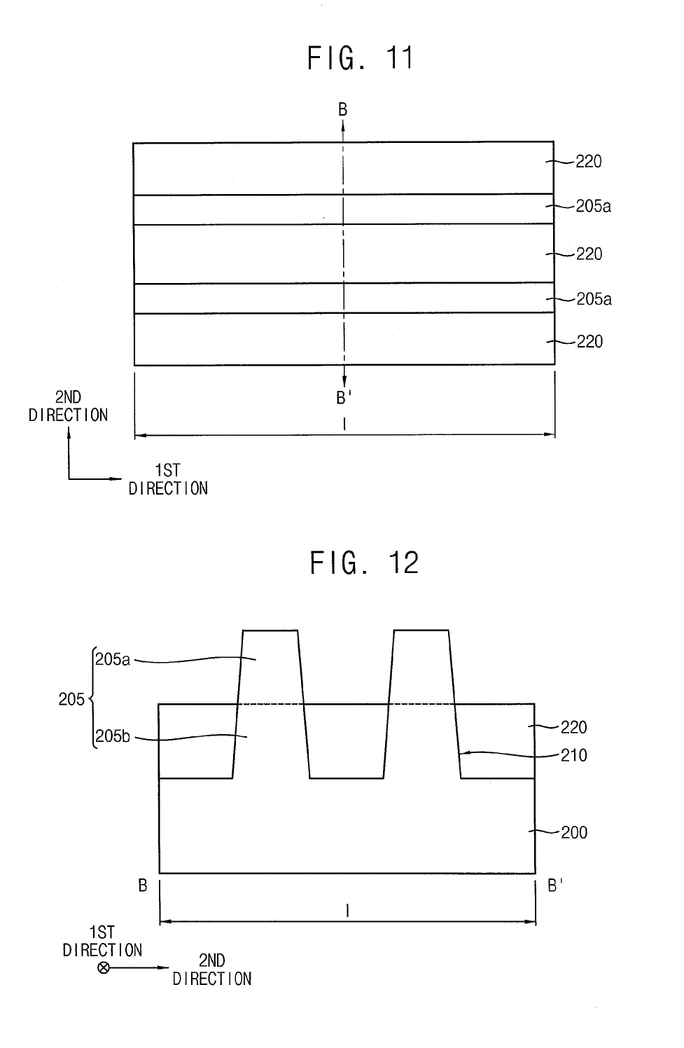

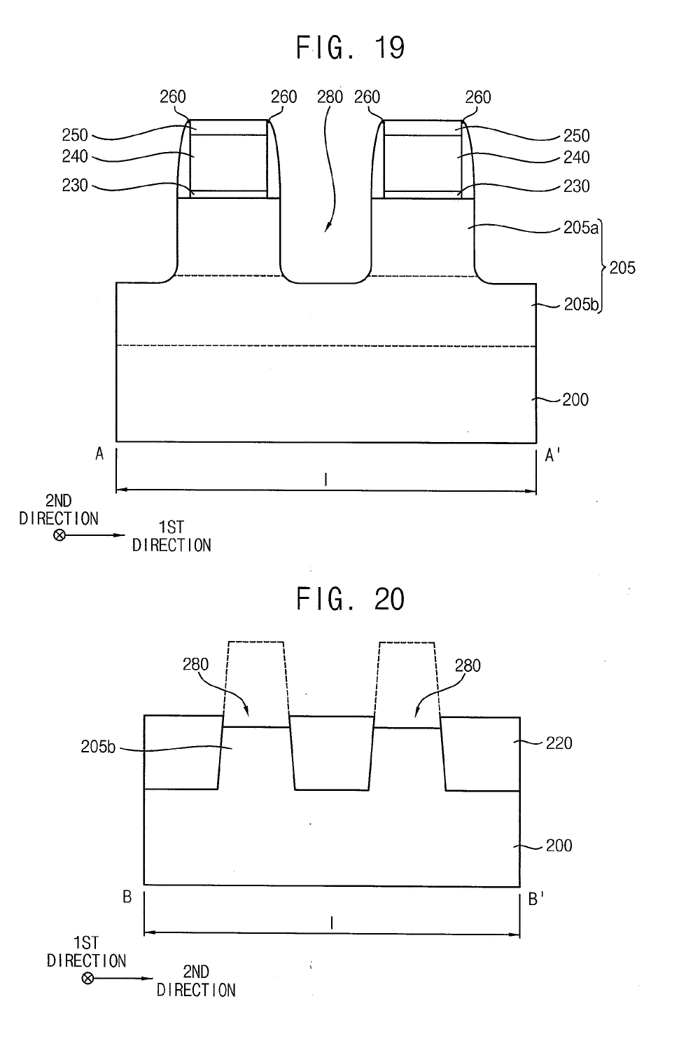

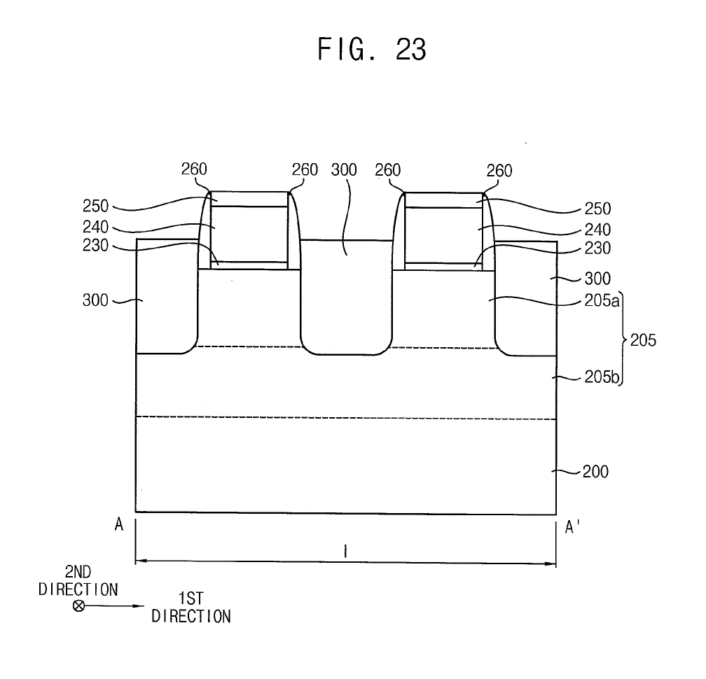

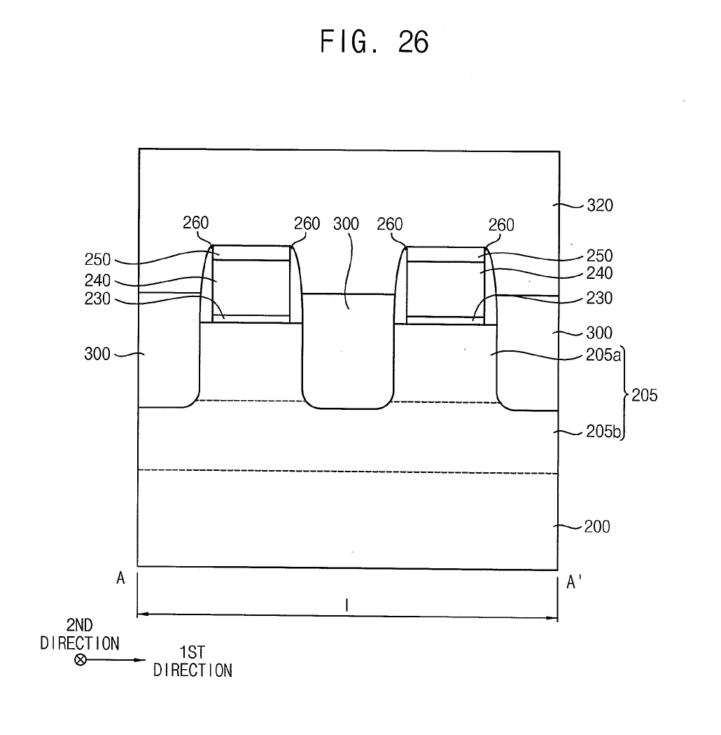

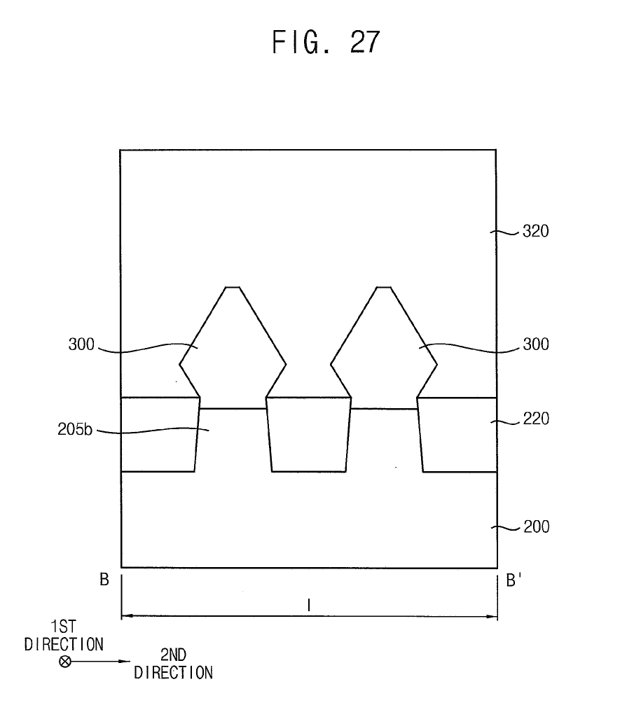

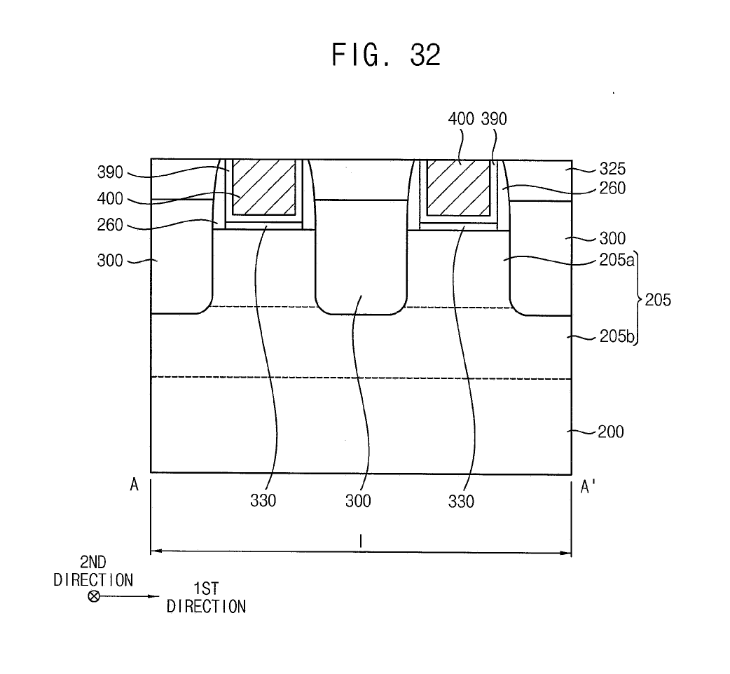

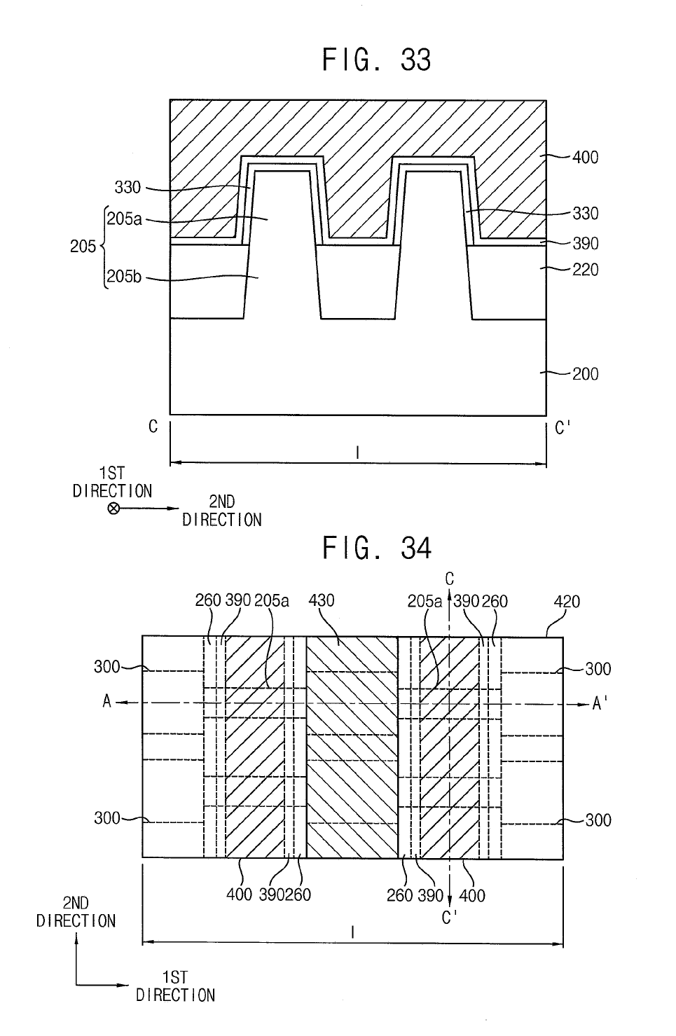

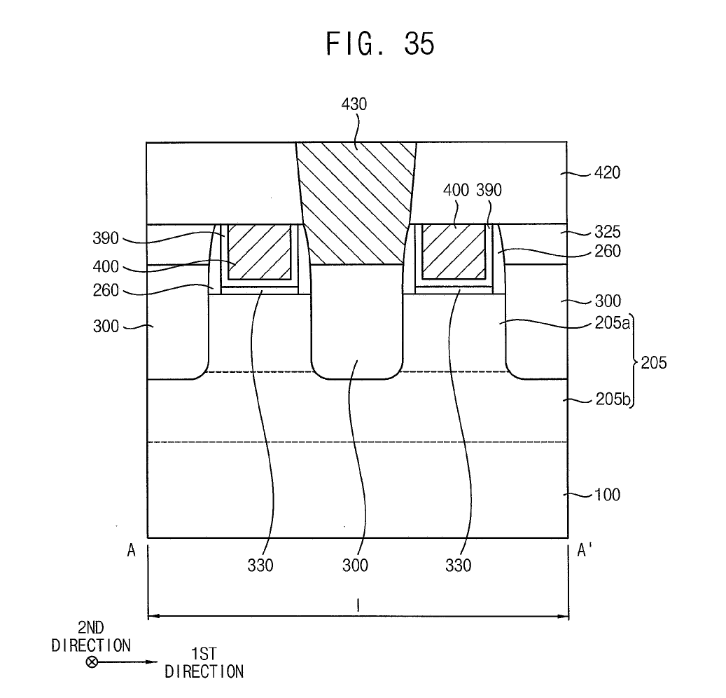

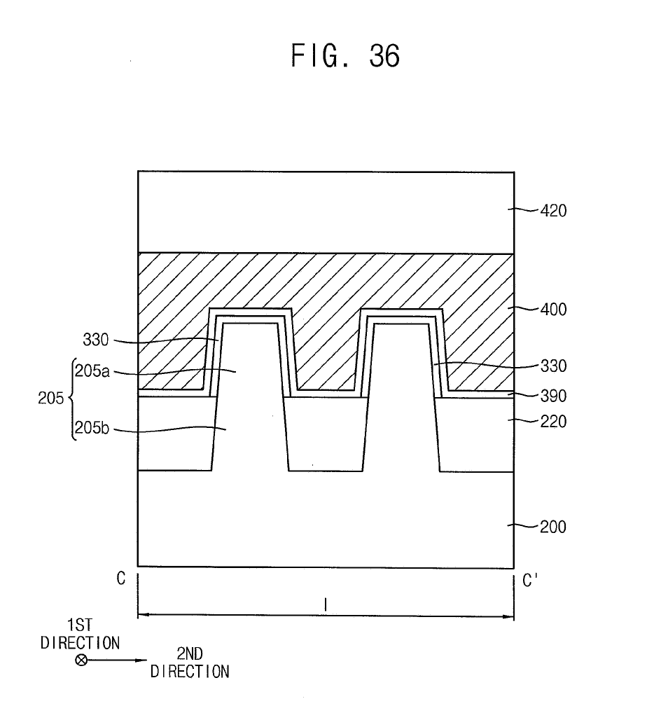

FIG. 9 is a flowchart illustrating stages of a method of manufacturing a semiconductor device in accordance with exemplary embodiments. FIG. 10 is a plan view of a wafer on which the semiconductor device may be formed. FIGS. 11 to 38 are plan views and cross-sectional views illustrating the method of manufacturing the semiconductor device.

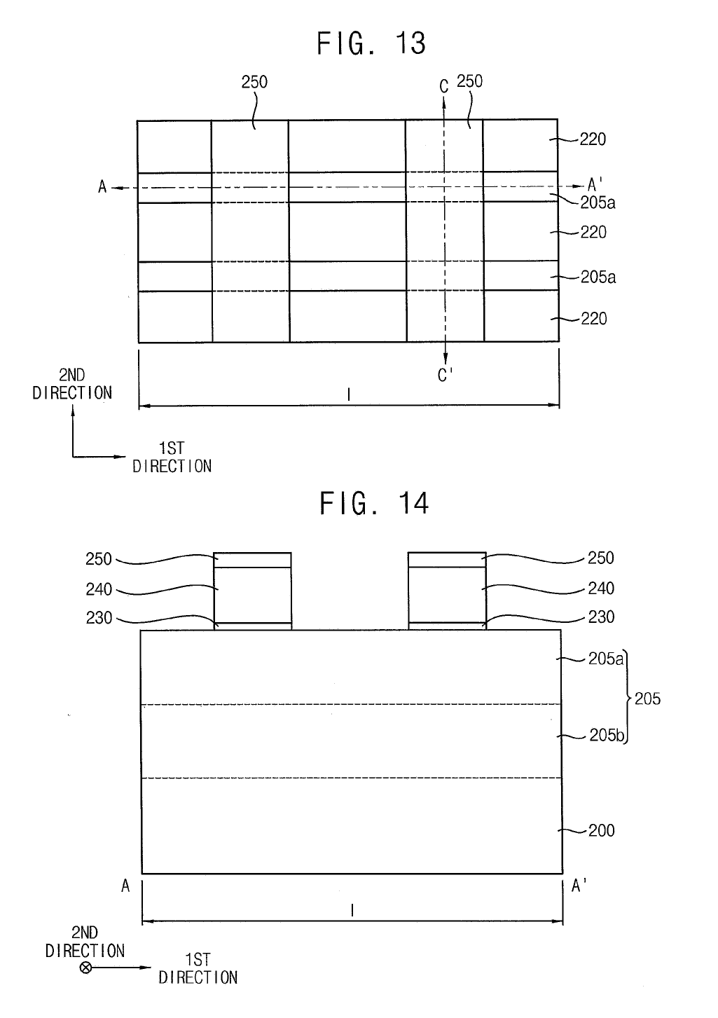

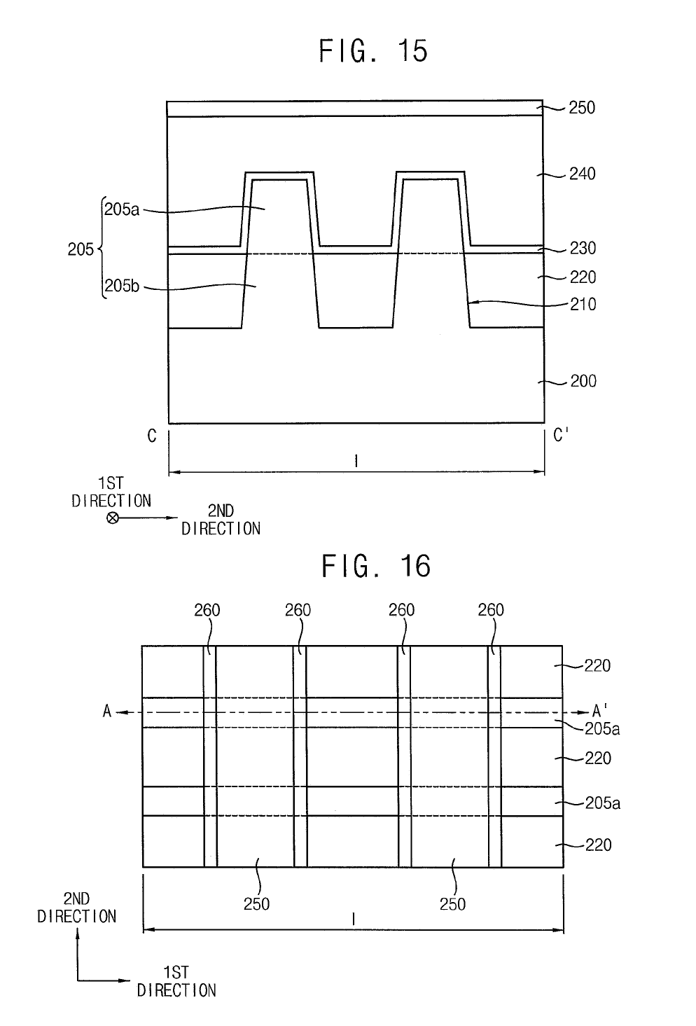

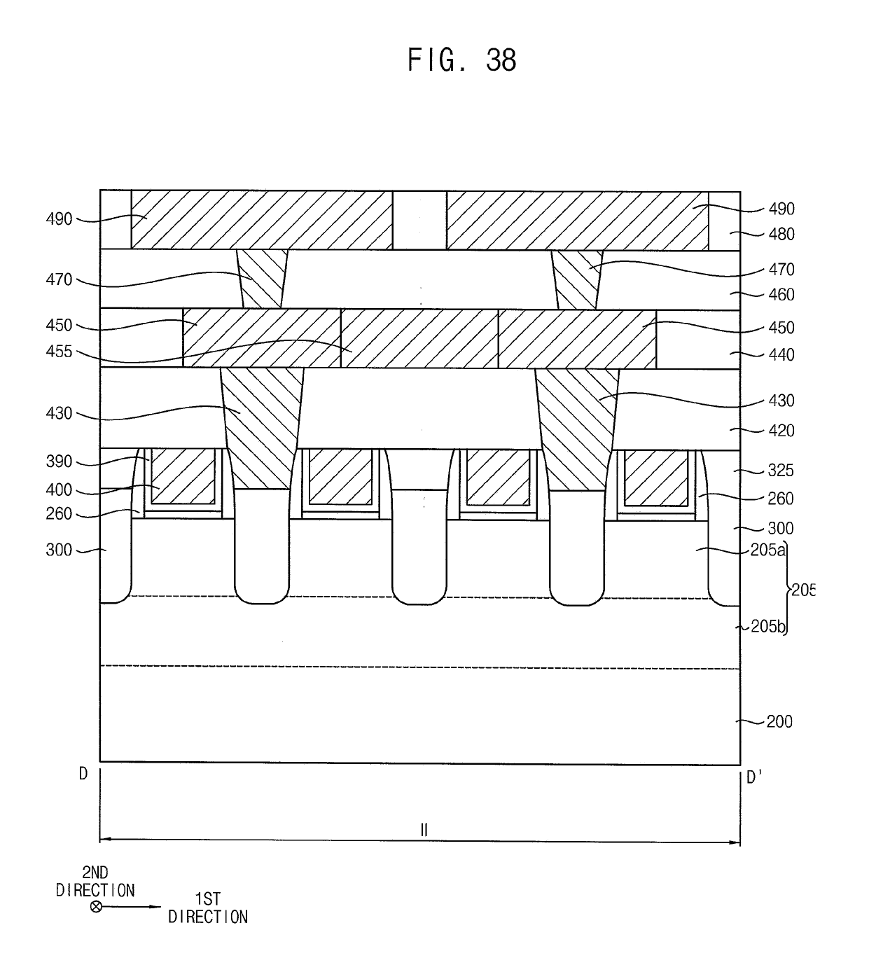

Particularly, FIGS. 11, 13, 16, 18, 22, 25, 28, 31 and 34 are plan views. FIGS. 14, 17, 19, 21, 23, 26, 29, 32, 35 and 37 are cross-sectional views taken along lines A-A′ of corresponding plan views. FIGS. 12, 20, 24A, 24B and 27 are cross-sectional views taken along lines B-B′ of corresponding plan views. FIGS. 15, 30, 33 and 36 are cross-sectional views taken along lines C-C′ of corresponding plan views. FIG. 38 is a cross-sectional view of a portion of a second region II of the wafer taken along a line D-D′ corresponding to the line A-A′ of a first region I of the wafer.

The exemplary method of manufacturing the semiconductor device may be performed using the method of forming the test structure for detecting bad patterns illustrated with reference to FIGS. 1 to 7A, 7B, 7C, and thus detailed descriptions thereon are omitted herein.

Referring to FIGS. 9 and 10, the semiconductor device may be formed on a wafer 200, and the wafer 200 may include first and second regions I, II.

The first region I may be a die region in which chips may be formed, and the second region II may be a scribe lane region that may be cut by sawing.

The chip may include, e.g., logic devices, memory devices, or the like, and various types of patterns may be formed therein. A test structure for determining as to whether the various types of patterns in the chip have desired characteristics or not may be formed in the second region II.

In step S310, a layout may be designed of a plurality of patterns to be formed in the die region I of the wafer 200 on which the chips including, e.g., logic devices, are to be formed.

In step S320, like steps S110 and S120, target patterns among the plurality of patterns in the chip may be classified into a plurality of groups.

Particularly, a plurality of target regions, each of which may include the target patterns therein, may be defined in the chip. All target patterns included in the target regions may be searched and enumerated, and the enumerated target patterns may be compared to each other.

In exemplary embodiments, each of the target patterns may be a wiring structure including a via, and lower and upper wirings on and beneath the via, respectively, and each of the target regions may include some or all portions of the wiring structure, however, the inventive concepts may not be limited thereto.

In step S330, like steps S150, a layout may be designed of chains that may be formed by connecting the target patterns classified into the plurality of groups.

In step S340, the plurality of patterns having the designed layout in step S310 may be formed in the die region I of the wafer 200, and in step S350, the chains having the designed layout in step S330 may be formed in the scribe lane region of the wafer 200. In exemplary embodiments, when the patterns are formed in the die region of the wafer 200, patterns substantially the same as or similar to the patterns in the die region may be also formed in the scribe lane region of the wafer 200. Alternatively, except when patterns corresponding to the chains are formed in the die region I of the wafer 200, no pattern except for an insulating interlayer may be formed in the scribe lane region II of the wafer 200.

Hereinafter, only the case in which, when the patterns are formed in the die region of the wafer 200, patterns substantially the same as or similar thereto are also formed in the scribe lane region II of the wafer 200 will be illustrated, and for the convenience of explanation, before the chains are formed, only the patterns formed in the die region of the wafer 200 will be illustrated.

Particularly, referring to FIGS. 11 and 12, an upper portion of the wafer 200 may be partially removed to form a trench 210, and an isolation layer 220 may be formed on the wafer 200 to fill the trench 210.

The wafer 200 may include a semiconductor material, e.g., silicon, germanium, or the like, or III-V compound semiconductor materials, e.g., GaP, GaAs, GaSb, or the like. In some embodiments, the wafer 200 may be a silicon-on-insulator (SOI) substrate or a germanium-on-insulator (GOI) substrate.

Before forming the trench 210, impurities may be implanted into the wafer 200 by an ion implantation process to form a well region (not shown). In exemplary embodiments, the well region may be formed by implanting p-type impurities, e.g., boron, aluminum, and the like. Alternatively, the well region may be formed by implanting n-type impurities, e.g., phosphorus, arsenic, and the like.

In exemplary embodiments, the isolation layer 220 may be formed by forming an insulation layer on the wafer 200 to sufficiently fill the trench 210, planarizing the insulation layer until a top surface of the wafer 200 may be exposed, and removing an upper portion of the planarized insulation layer to expose an upper portion of the trench 210. When the upper portion of the planarized insulation layer is removed, an upper portion of the wafer 200 adjacent thereto may be also partially removed to have a narrow width. The insulation layer may be formed of an oxide, e.g., silicon oxide.

As the isolation layer 220 is formed, a field region, of which a top surface may be covered by the isolation layer 220 and an active region of which a top surface may not be covered by the isolation layer 220, may be defined in the wafer 200. The active region may protrude from the isolation layer 220 and have a fin-like shape so as to be referred to as an active fin 205. In an exemplary embodiment, the active fin 205 may include a lower portion 205b of which a sidewall may be covered by the isolation layer 220, and an upper portion of which a sidewall may not be covered by the isolation layer 220, but may protrude from a top surface of the isolation layer 220.

In exemplary embodiments, the active fin 205 may extend in a first direction substantially parallel to the top surface of the wafer 200, and a plurality of active fins 205 may be formed in a second direction substantially parallel to the top surface of the wafer 200 and having a given angle with respect to the first direction. In an exemplary embodiment, the second direction may have an angle of 90 degrees with respect to the first direction, and thus the first and second directions may be substantially perpendicular to each other.

Referring to FIGS. 13 to 15, a dummy gate layer structure may be formed on the wafer 200.

The dummy gate layer structure may be formed by sequentially forming a dummy gate insulation layer, a dummy gate electrode layer and a dummy gate mask layer on the active fin 205 of the wafer 200 and the isolation layer 220, patterning the dummy gate mask layer through a photolithography process using a photoresist pattern (not shown) to form a dummy gate mask 250, and sequentially etching the dummy gate electrode layer and the dummy gate insulation layer using the dummy gate mask 250 as an etching mask. Thus, the dummy gate structure may be formed to include a dummy gate insulation pattern 230, a dummy gate electrode 240 and the dummy gate mask 250 sequentially stacked on the active fin 205 of the wafer 200 and a portion of the isolation layer 220 adjacent thereto in the second direction.

The dummy gate insulation layer may be formed of an oxide, e.g., silicon oxide, the dummy gate electrode layer may be formed of, e.g., polysilicon, and the dummy gate mask layer may be formed of a nitride, e.g., silicon nitride. The dummy gate insulation layer, the dummy gate electrode layer and the dummy gate mask layer may be formed by a chemical vapor deposition (CVD) process, a physical vapor deposition (PVD) process, an atomic layer deposition (ALD) process, or the like. Alternatively, the dummy gate insulation layer may be formed by a thermal oxidation process on an upper portion of the active fin 205.

In exemplary embodiments, the dummy gate structure may be formed to extend on the active fins 205 of the wafer 200 and the isolation layer 220 in the second direction, and a plurality of dummy gate structures may be formed in the first direction at a constant distance from each other.

After forming the dummy gate structure, impurities may be implanted into the wafer 200 by an ion implantation process to form a halo region (not shown) and a lightly doped drain (LDD) region (not shown). In exemplary embodiments, the halo region may be formed by implanting p-type impurities, e.g., boron, aluminum, and the like, and the LDD region may be formed by implanting n-type impurities, e.g., phosphorus, arsenic, and the like. Alternatively, the halo region may be formed by implanting n-type impurities, and the LDD region may be formed by implanting p-type impurities.

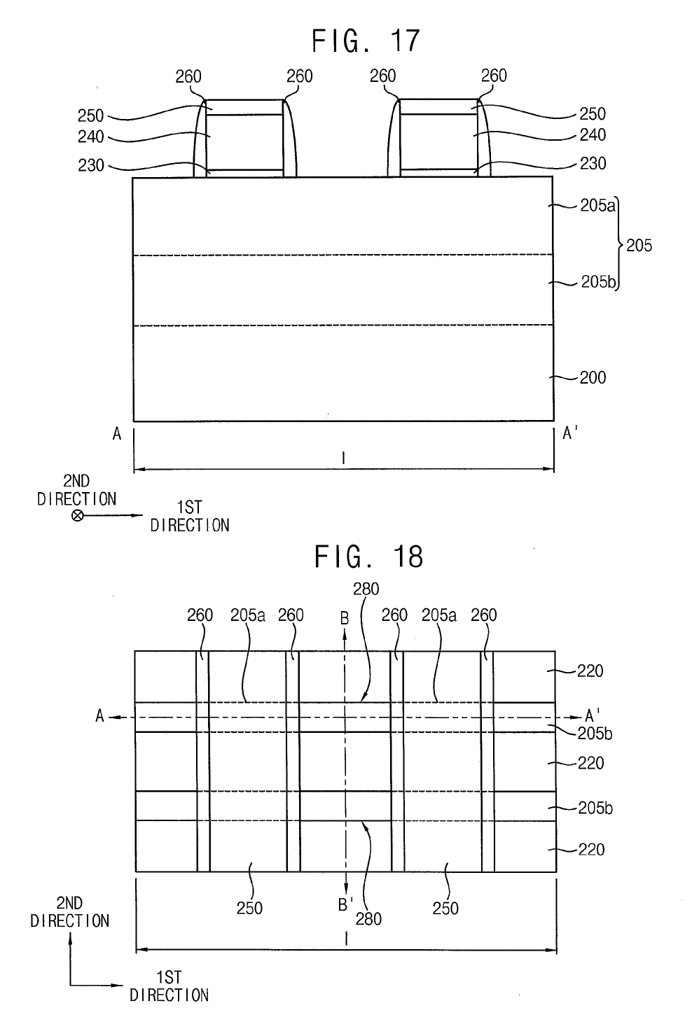

Referring to FIGS. 16 and 17, a gate spacer 260 may be formed on a sidewall of the dummy gate structure. A fin spacer (not shown) may be further formed on a sidewall of the active fins 205.

In exemplary embodiments, the gate spacer 260 may be formed by forming a spacer layer on the dummy gate structure, the active fin 205, and the isolation layer 220, and anisotropically etching the spacer layer. The spacer layer may be formed of a low-k dielectric material including oxygen, e.g., silicon oxynitride, silicon oxycarbonitride, and the like.

In exemplary embodiments, the gate spacer 260 may be formed on sidewalls of the dummy gate structure opposed to each other in the first direction.

Referring to FIGS. 18 to 20, a portion of the active fin 205 not covered by the dummy gate structure and the gate spacer 260 may be partially etched using the dummy gate structure and the gate spacer 260 as an etching mask to form a recess 280.

In exemplary embodiments, the recess 280 may be formed by removing the upper portion 205a of the active fin 205 and partially removing the lower portion 205b of the active fin 205. Thus, the recess 280 may have a bottom lower than a top of the lower portion 205b of the active fin 205 at which the recess 280 is not formed.

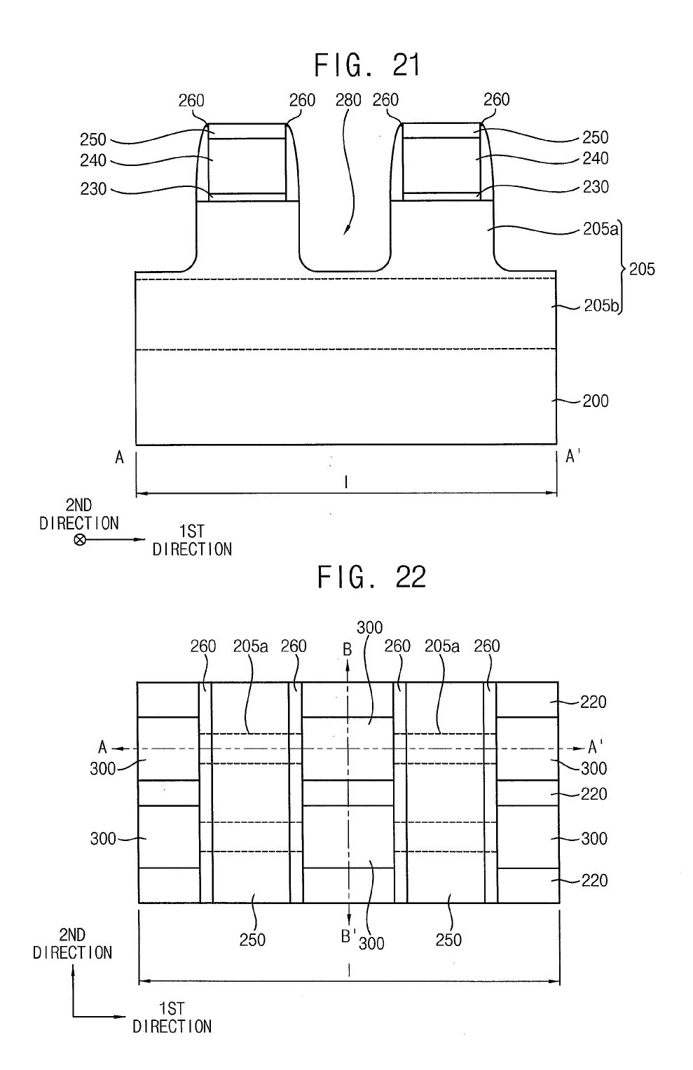

Alternatively, Referring to FIG. 21, the recess 280 may be formed by partially removing only the upper portion 205a of the active fin 205, and thus the recess 280 may have a bottom higher than a bottom of the upper portion 205a of the active fin 205 at which the recess 280 is not formed.

Hereinafter, for the convenience of explanation, only the case in which the recess 280 has the bottom lower than the top of the lower portion 205b of the active fin 205 will be illustrated.

The anisotropic etching process for forming the gate spacer 260 and the etching process for forming the recess 280 may be performed in-situ.

Referring to FIGS. 22, 23 and 24A, an epitaxial layer 300 may be formed to fill the recess 280.

In exemplary embodiments, the epitaxial layer 300 may be formed by a selective epitaxial growth (SEG) process using a portion of the active fin 205 exposed by the recess 280, i.e., a top surface of the lower portion 205b of the active fin 205 and a sidewall of the upper portion 205a of the active fin 205 as a seed.

In an exemplary embodiment, the SEG process may be performed using a silicon source gas, e.g., disilane (Si₂H₆) gas so that a single crystalline silicon layer may be formed. An n-type impurity source gas, e.g., phosphine (PH₃) gas may be also used to form a single crystalline silicon layer doped with n-type impurities. Alternatively, the SEG process may be performed using a silicon source gas, e.g., disilane (Si₂H₆) gas and a carbon source gas, e.g., monomethylsilane (SiH₃CH₃) gas so that a single crystalline silicon carbide layer may be formed. An n-type impurity source gas, e.g., phosphine (PH₃) gas may be also used to form a single crystalline silicon carbide layer doped with n-type impurities.

In another exemplary embodiment, the SEG process may be performed using a silicon source gas, e.g., dichlorosilane (SiH₂Cl₂) gas, and a germanium source gas, e.g., germane (GeH₄) gas so that a single crystalline silicon-germanium layer may be formed. A p-type impurity source gas, e.g., diborane (B₂H₆) gas may be also used to form a single crystalline silicon-germanium layer doped with p-type impurities.

In exemplary embodiments, the epitaxial layer 300, which may be the single crystalline silicon layer doped with n-type impurities, the silicon carbide layer doped with n-type impurities, or the single crystalline silicon-germanium layer doped with p-type impurities, may grow both in vertical and horizontal directions, and an upper portion of the epitaxial layer 300 may have a cross-section taken along the second direction of which a shape may be a pentagon or hexagon.

In exemplary embodiments, the epitaxial layer 300 may fill the recess 280 to cover a lower sidewall of the gate spacer 260.

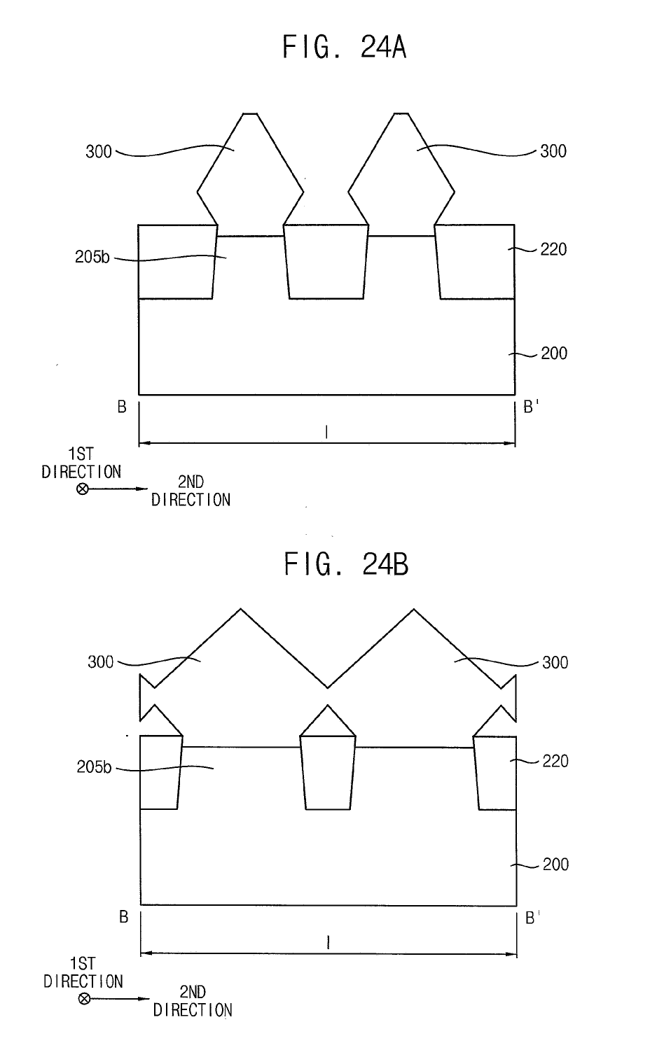

Referring to FIG. 24B, neighboring ones of the epitaxial layers 300 may be merged with each other. When the neighboring ones of the epitaxial layer 300 is spaced apart from each other at a short distance, some or all of the epitaxial layers 300 each of which may grow from the active fin 205 may be merged with each other.

Impurities may be implanted into the active fin 205 by an ion implantation process to form an impurity region (not shown).

In exemplary embodiments, the impurity region may be formed by implanting n-type impurities, e.g., phosphorus, arsenic, and the like. The ion implantation process may be performed using the dummy gate structures and the gate spacers 260 as an ion implantation mask, and an annealing process may be further performed to diffuse the impurities into neighboring regions.

Thus, the impurities may be implanted into the epitaxial layer 300 and a portion of the active fin 205 under the epitaxial layer 300, and hereinafter, only the portion of the active fin 205 doped with impurities may be referred to as the impurity region. The epitaxial layer 300 together with the impurity region may serve as a source/drain region of a negative-channel metal oxide semiconductor (NMOS) transistor.

Alternatively, the impurities may be formed by implanting p-type impurities, e.g., boron, aluminum, and the like, and the epitaxial layer 300 together with the impurity region may serve as a source/drain region of a positive-channel metal oxide semiconductor (PMOS) transistor.

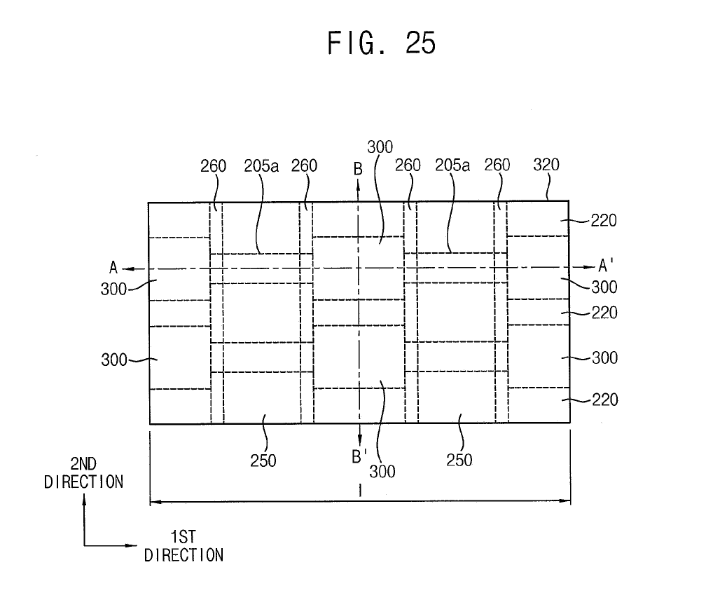

Referring to FIGS. 25 to 27, a first insulating interlayer 320 may be formed on the dummy gate structure, the gate spacer 260, the epitaxial layer 300 and the isolation layer 220 to have a top surface higher than that of the dummy gate structure. The first insulating interlayer 320 may be formed of an oxide, e.g., silicon oxide.

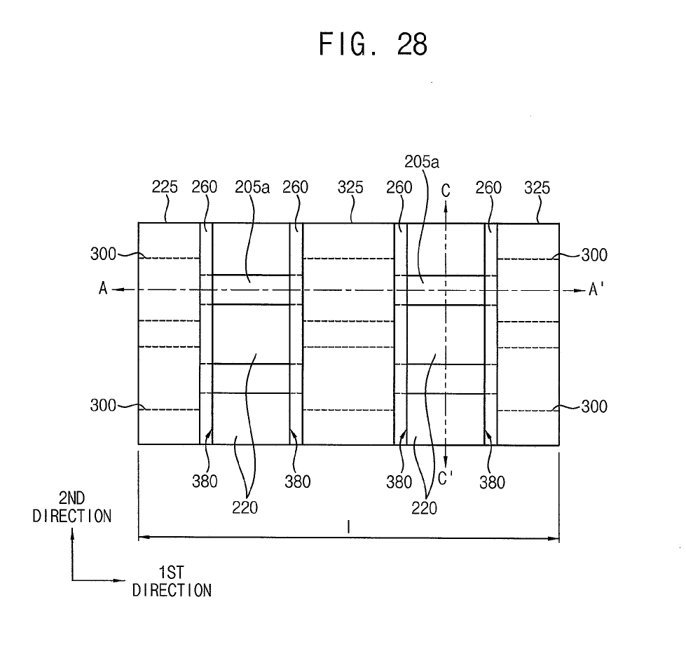

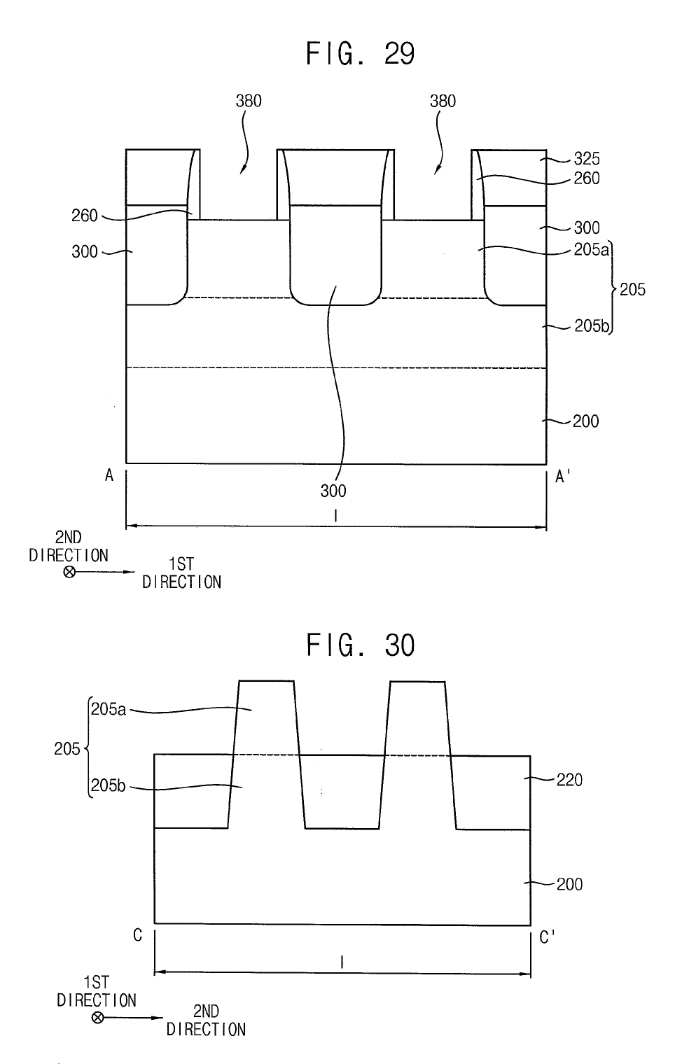

Referring to FIGS. 28 to 30, the first insulating interlayer 320 may be planarized until a top surface of the dummy gate electrode 240 of the dummy gate structure may be exposed to form a first insulating interlayer pattern 325.

In exemplary embodiments, the planarization process may be performed by a chemical mechanical polishing (CMP) process and/or an etch back process. In the planarization process, the dummy gate mask 250 of the dummy gate structure and an upper portion of the gate spacer 260 may be also removed.

The exposed dummy gate electrode 240 and the dummy gate insulation pattern 230 thereunder may be removed to form an opening 380 exposing top surfaces of the active fin 205 and the isolation layer 220.

In exemplary embodiments, the dummy gate electrode 240 may be removed by performing a dry etching process first and then a wet etching process. In exemplary embodiments, the dummy gate insulation pattern 230 may be removed by a wet etching process using hydrogen fluoride (HF) as an etching solution.

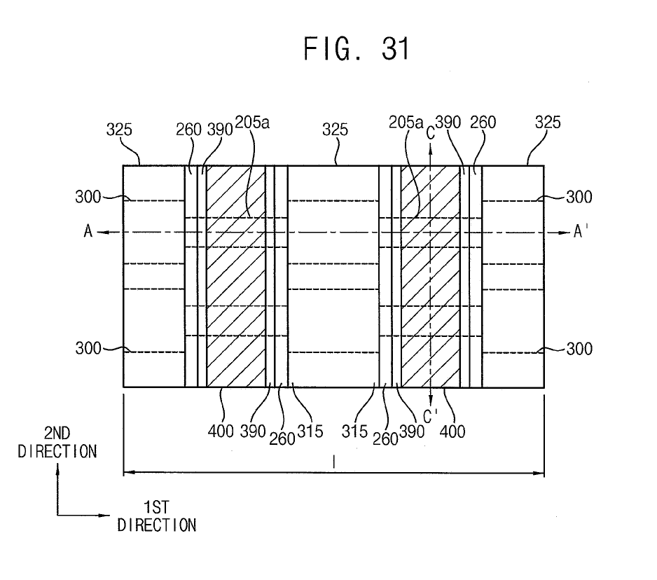

Referring to FIGS. 31 to 33, an interface pattern 330, a gate insulation pattern 390, and a gate electrode 400 may be sequentially formed to fill the opening 380.

Particularly, a thermal oxidation process may be performed on the top surface of the active fin 205 of the wafer 200 exposed by the opening 380 to form an interface pattern 330 including silicon oxide. In some cases, the interface pattern 330 may not be formed.

A gate insulation layer may be formed on an upper surface of the interface pattern 330, an upper surface of the isolation layer 220, a sidewall of the opening 380, and an upper surface of the first insulating interlayer pattern 325, and a gate electrode layer may be formed on the gate insulation layer to sufficiently fill a remaining portion of the opening 380.

In exemplary embodiments, the gate insulation layer may be formed of a metal oxide having a high dielectric constant, e.g., hafnium oxide, tantalum oxide, zirconium oxide, or the like.

The gate electrode layer may be formed of a material having a low resistance, e.g., a metal such as aluminum, copper, tantalum, or the like, or doped polysilicon, by a CVD process, a PVD process, an ALD process, or the like. An annealing process, e.g., a rapid thermal annealing (RTA) process, a spike rapid thermal annealing (spike-RTA) process, a flash-RTA process, a laser annealing process, and the like. may be further performed on the gate electrode layer. Alternatively, the gate electrode layer may be formed of polysilicon doped with impurities.

The gate electrode layer and the gate insulation layer may be planarized until a top surface of the first insulating interlayer pattern 325 may be exposed to form the gate insulation pattern 390 on the upper surface of the interface pattern 330, the upper surface of the isolation layer 220 and the sidewall of the opening 380, and the gate electrode 400 may be formed on the gate insulation pattern 390 to fill the remaining portion of the opening 380. Thus, a bottom and a sidewall of the gate electrode 400 may be covered by the gate insulation pattern 390. In exemplary embodiments, the planarization process may be performed by a CMP process and/or an etch back process.

The interface pattern 330, the gate insulation pattern 390 and the gate electrode 400 sequentially stacked may form a gate structure, and the gate structure and the source/drain region may form an NMOS transistor or a PMOS transistor.

Referring to FIGS. 34 to 36, a second insulating interlayer 420 may be formed on the first insulating interlayer pattern 325 to cover the transistor, and a contact plug 430 may be formed through the second insulating interlayer 420 and the first insulating interlayer pattern 325 to contact a top surface of the epitaxial layer 300.

In exemplary embodiments, the contact plug 430 may be formed by forming an opening (not shown) through the second insulating interlayer 420 and the first insulating interlayer pattern 325 to expose the top surface of the epitaxial layer 300, forming a conductive layer on the exposed top surface of the epitaxial layer 300 and the second insulating interlayer 420, and planarizing the conductive layer until a top surface of the second insulating interlayer 420 may be exposed.

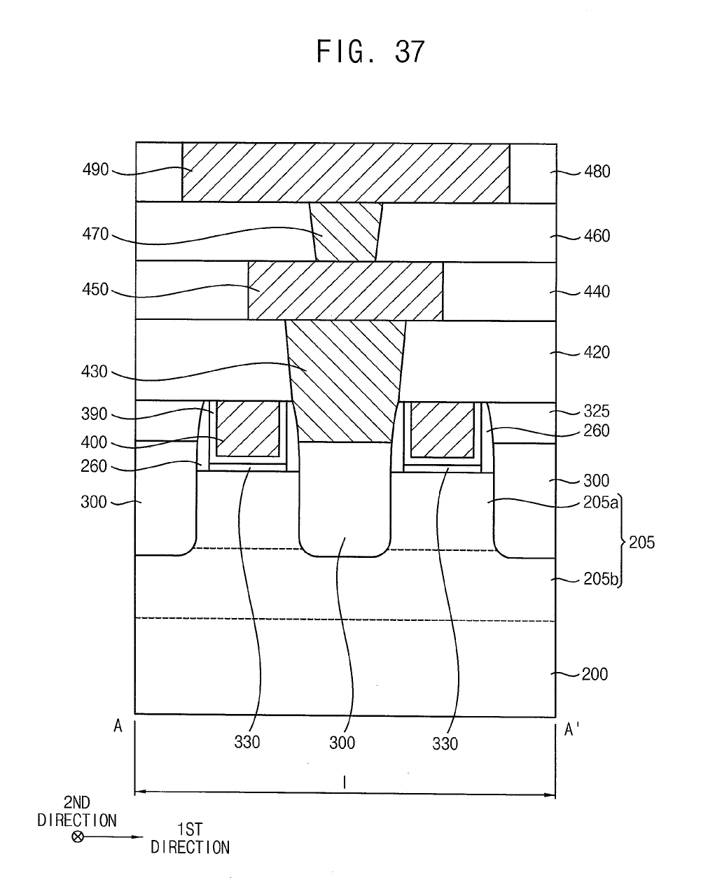

Referring to FIG. 37, wiring structures may be formed on the second insulating interlayer 420 and the contact plug 430 in the first region I of the wafer 200.

Particularly, a third insulating interlayer 440 may be formed on the second insulating interlayer 420 and the contact plug 430, and a lower wiring 450 may be formed through the third insulating interlayer 440 to contact the contact plug 430. A fourth insulating interlayer 460 may be formed on the third insulating interlayer 440 and the lower wiring 450, and a via 470 may be formed through the fourth insulating interlayer 460 to contact the lower wiring 450. A fifth insulating interlayer 480 may be formed on the fourth insulating interlayer 460 and the via 470, and an upper wiring 490 may be formed through the fifth insulating interlayer 480 to contact the via 470. Thus, the wiring structures each of which may include the lower wiring 450, the via 470 and the upper wiring 490 may be formed.

Referring to FIG. 38, patterns substantially the same as those formed in the first region I may be also formed in the second region II of the wafer 200.

However, chains having the designed layout in step S330 may be formed. That is, wiring structures substantially the same as some portions of the wiring structures in the first region I, and a connection pattern 455 connecting the wiring structures may be formed. FIG. 38 shows that the connection pattern 455 connecting the lower wirings 450 to each other. However, in some cases, a connection pattern (not shown) connecting the upper wirings 490 to each other may be formed. The chains may define a test structure.

Additional wiring structures and insulating interlayers may be further formed.

In step S360, a current may be applied to the test structure to measure a resistance thereof, so that bad patterns or failure in the target patterns, i.e., the wiring structure may be detected.

The second region II of the wafer 200 may be cut by a sawing process, and thus the wafer 200 may be divided into a plurality of chips. Each of the divided chips may be packaged to complete the semiconductor device. Alternatively, the packaging process may be performed before the sawing process.

The above processes may be repeatedly performed to mass-produce the chips including the logic devices or memory devices.

When bad patterns or failures are detected in step S360, the next manufacture process may be performed taking into consideration the bad patterns or failures. That is, when the layout of the patterns to be formed in the die region I of the wafer 200 is designed, the layout may be modified in consideration of the bad patterns or failures detected in step S360, and thus the patterns may be formed according to the modified design in the next manufacture process.

The above method of forming the test structure for detecting bad patterns, and the method of detecting the bad patterns and the method of manufacturing the semiconductor device may be applied to methods of manufacturing various types of memory devices and systems including a wiring structure. For example, this method may be applied to logic devices such as central processing units (CPUs), main processing units (MPUs), or application processors (APs), or the like. Additionally, this method may be applied to volatile memory devices such as DRAM devices or SRAM devices, or non-volatile memory devices such as flash memory devices, PRAM devices, MRAM devices, ReRAM devices, or the like.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A method of forming a test structure for detecting bad patterns, the method comprising:
classifying patterns in a chip into a plurality of groups;
designing a layout of chains, the chains being formed by connecting the patterns in each of the groups to each other; and
forming a test structure having the layout of chains in a region of the chip.

2. The method of claim 1, wherein the classifying patterns in a chip into a plurality of groups includes:
searching all of the target patterns in the chip to classify the searched target patterns into the plurality of groups.

3. The method of claim 1, wherein the classifying patterns in a chip into a plurality of groups includes:
defining a plurality of target regions in the chip, each of the target regions including target patterns; and
selecting at least one of the target patterns substantially the same as, or similar to, each other by comparing the target patterns in the target regions to each other to classify the at least one of the target patterns into a corresponding one of the groups.

4. The method of claim 3, further comprising, after the defining a plurality of target regions in the chip, removing a portion of each of the target patterns close to an edge of each of the target regions having a size smaller than those of other portions of each of the target patterns.

5. The method of claim 3, wherein the target patterns include a via, and upper and lower wirings connected to top and bottom surfaces of the via.

6. The method of claim 5, wherein the classifying patterns in a chip into a plurality of groups is performed in consideration of shapes of the upper and lower wirings or a location of the via between the upper and lower wirings.

7. The method of claim 5, wherein the classifying patterns in a chip into a plurality of groups is performed in consideration of widths and directions of the upper and lower wirings.

8. The method of claim 5, wherein the designing a layout of chains includes:
forming an upper connection pattern connecting the upper wirings of neighboring ones of the target patterns, or forming a lower connection pattern connecting the lower wirings of neighboring ones of the target patterns to form the chains.

9. The method of claim 8, wherein the upper connection pattern or the lower connection pattern extends in a first direction, or includes a first portion extending in the first direction and a second direction extending in a second direction substantially perpendicular to the first direction.

10. The method of claim 8, wherein the upper wiring or the lower wiring contacts the via and extends in the first direction, and the upper connection pattern or the lower connection pattern corresponding thereto is connected to end portions of the upper wiring or the lower wiring relatively distant from the via among end portions of the upper wiring or the lower wiring in the first direction.

11. The method of claim 8, wherein the upper wiring or the lower wiring includes a first portion contacting the via and extending in the first direction and a second portion extending in a second direction substantially perpendicular to the first direction, and the upper connection pattern or the lower connection pattern corresponding thereto is connected to end portions of the upper wiring or the lower wiring relatively distant from the via among end portions of the upper wiring or the lower wiring in the first and second directions.

12. The method of claim 1, further comprising, after the classifying patterns in a chip into a plurality of groups, removing at least one of the groups having a low possibility of failure.

13. The method of claim 1, wherein the designing a layout of chains being formed by connecting patterns in each of the groups to each other is automatically performed by programming.

14. A method of forming a test structure for detecting bad patterns, the method comprising:
i) defining a plurality of target regions in a chip, each of the target regions including target patterns;
ii) comparing the target patterns in the target regions to each other to classify the compared target patterns into a plurality of groups; and
iii) connecting the target patterns in each of the groups to form chains.

15. The method of claim 14, wherein the target patterns includes a via, and upper and lower wirings connected to top and bottom surfaces of the via.

16. The method of claim 14,
wherein steps i), ii) and iii) are automatically performed by programming to design a layout of the chains, and
the method further includes forming a test structure by forming a layout of the chains in a region of the chip.

17. A method of detecting bad patterns, the method comprising:
classifying patterns in a chip into a plurality of groups;
designing a layout of chains, the chains being formed by connecting patterns in each of the groups to each other;
forming chains having the designed layout in a region of the chip as a test structure; and
detecting the bad patterns in the patterns by applying a current to the test structure to measure a resistance thereof.

18. The method of claim 17, wherein the classifying patterns in a chip into a plurality of groups includes:
defining a plurality of target regions in the chip, each of the target regions including target patterns; and
selecting at least one of the target patterns substantially the same as or similar to each other by comparing the target patterns in the target regions to each other to classify the at least one of the target patterns into a corresponding one of the groups.

19. The method of claim 18, wherein the target patterns includes a via, and upper and lower wirings connected to top and bottom surfaces of the via.

20. The method of claim 19, wherein the classifying patterns in a chip into a plurality of groups is performed in consideration of shapes of the upper and lower wirings or a location of the via between the upper and lower wirings.
